(19) United States
(12) Patent Application Publication
(10) Pub. No.: US 2025/0107008 A1
(43) Pub. Date: Mar. 27, 2025

(54) PRINTED CIRCUIT BOARD

(71) Applicant: SAMSUNG ELECTRO-MECHANICS CO., LTD., Suwon-si (KR)

(72) Inventors: Hyun Hu LEE, Suwon-si (KR); Jong Eun PARK, Suwon-si (KR); Chang Hwa PARK, Suwon-si (KR); Sang Ho JEONG, Suwon-si (KR); Sang Won HAN, Suwon-si (KR); Deok Hong JO, Suwon-si (KR)

(73) Assignee: SAMSUNG ELECTRO-MECHANICS CO., LTD., Suwon-si (KR)

(21) Appl. No.: 18/783,666

(22) Filed: Jul. 25, 2024

(30) Foreign Application Priority Data
Sep. 25, 2023 (KR) 10-2023-0128292

(51) Int. Cl. H05K 3/40; H05K 1/11; H05K 1/18; H05K 3/28; H05K 3/34

(52) U.S. Cl. CPC H05K 3/4007; H05K 1/112; H05K 1/181; H05K 3/287; H05K 3/3452; H05K 2201/099; H05K 2203/1377

(57) ABSTRACT

A printed circuit board includes a wiring portion including one or more insulating layers, one or more wiring layers respectively disposed on or in the one or more insulating layers, a first pad disposed on a lowermost insulating layer, of the one or more insulating layers, and a second pad disposed on an uppermost insulating layer, of the one or more insulating layers, a first solder resist layer disposed on a lower side of the wiring portion to cover at least a portion of the first pad, the first solder resist layer having a first opening, on the first pad, a second solder resist layer disposed on an upper side of the wiring portion to cover at least a portion of the second pad, a first surface treatment layer disposed on at least a portion of the first pad, and a barrier layer disposed on the first solder resist layer.

### CROSS-REFERENCE TO RELATED APPLICATION(S)

This application claims benefit of priority to Korean Patent Application No. 10-2023-0128292 filed on Sep. 25, 2023 in the Korean Intellectual Property Office, the disclosure of which is incorporated herein by reference in its entirety.

### TECHNICAL FIELD

The present disclosure relates to a printed circuit board.

Multichip packages including a memory chip such as a high bandwidth memory (HBM) and a processor chip such as a central processing unit (CPU), a graphics processing unit (GPU), an application specific integrated circuit (ASIC), or a field programmable gate array (FPGA) have been used to process data, which has been exponentially increasing due to recent developments in artificial intelligence (AI) technology. In particular, the number of CPU and GPU cores of server products is rapidly increasing, and it is necessary to respond to finer chip metal post pitches. Research has been conducted to form a finer pad on a board for connection between a chip and the board, and to increase yield while improving the reliability of connection between the chip and the board.

### SUMMARY

An aspect of the present disclosure provides a printed circuit board on which an electronic component and a semiconductor chip are mounted, the printed circuit board capable of implementing a metal post having a fine pitch.

Another aspect of the present disclosure provides a printed circuit board including a pad on a lower surface thereof, a metal post on an upper surface thereof, and a surface treatment layer, the printed circuit board having no defects caused by galvanic corrosion from the pad and the surface treatment layer, when the metal post is disposed.

Another aspect of the present disclosure provides a printed circuit board having improved reliability.

Another aspect of the present disclosure provides a printed circuit board including a wiring portion including one or more insulating layers, one or more wiring layers respectively disposed on or in the one or more insulating layers, a first pad disposed on a lowermost insulating layer, among the one or more insulating layers, and a second pad disposed on an uppermost insulating layer, among the one or more insulating layers, a first solder resist layer disposed on a lower side of the wiring portion to cover at least a portion of the first pad, the first solder resist layer having a first opening, on the first pad, a second solder resist layer disposed on an upper side of the wiring portion to cover at least a portion of the second pad, a first surface treatment layer disposed on at least a portion of the first pad, and a barrier layer disposed on the first solder resist layer. A thickness of the barrier layer may be less than a thickness of the first pad.

According to another aspect of the present disclosure, a printed circuit board is provided including a wiring portion including one or more insulating layers, one or more wiring layers respectively disposed on or in the one or more insulating layers, a first pad disposed on a lowermost insulating layer, among the one or more insulating layers, and a second pad disposed on an uppermost insulating layer, among the one or more insulating layers, a first solder resist layer disposed on a lower side of the wiring portion to cover at least a portion of the first pad, the first solder resist layer having a first opening, on the first pad, a second solder resist layer disposed on an upper side of the wiring portion to cover at least a portion of the second pad, a first surface treatment layer disposed on at least a portion of the first pad, and a barrier layer disposed on the first solder resist layer. The barrier layer may include an inorganic oxide film.

According to example embodiments of the present disclosure, a printed circuit board on which an electronic component and a semiconductor chip are mounted may implement a metal post having a fine pitch.

The printed circuit board including a pad on a lower surface thereof, a metal post on an upper surface thereof, and a surface treatment layer, may have no defects caused by galvanic corrosion from the pad and surface treatment layer, when the metal post is disposed.

The printed circuit board may have improved reliability.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a schematic block diagram of an example of an electronic device system;

FIG. 2 is a schematic perspective view of an example of an electronic device;

FIGS. 3A and 3B are schematic cross-sectional views of a printed circuit board according to an example;

FIGS. 4A and 4B are schematic cross-sectional views of a printed circuit board according to another example; and

FIGS. 5 to 15 are schematic cross-sectional views of a method of manufacturing a printed circuit board according to an example.

### DETAILED DESCRIPTION

Hereinafter, the present disclosure will be described with reference to the accompanying drawings. The shapes and sizes of components in the drawings may be exaggerated or reduced for clearer description.

### Electronic Device

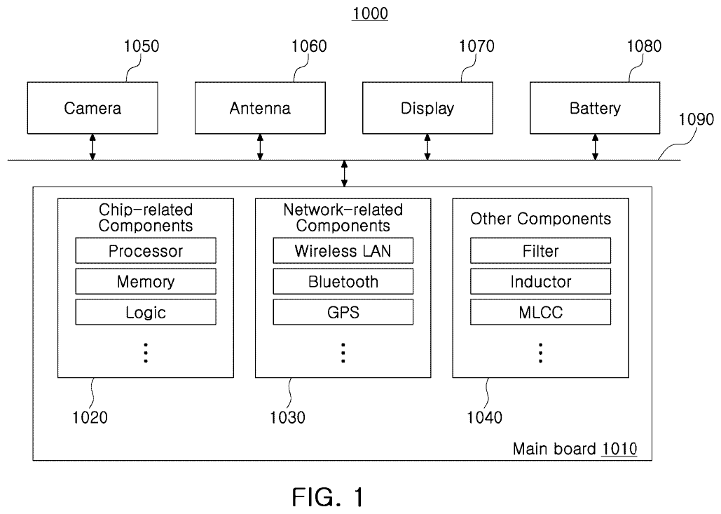

FIG. 1 shows an example schematic block diagram of an electronic device system.

Referring to FIG. 1, an electronic device 1000 may accommodate a mainboard 1010. The mainboard 1010 may include chip-related components 1020, network-related components 1030, and other components 1040, physically or electrically connected thereto. Such components may be connected to other components to be described below to form various signal lines 1090.

The chip-related components 1020 may include a memory chip such as a volatile memory (for example, a dynamic random access memory (DRAM)), a non-volatile memory (for example, a read only memory (ROM)), or a flash memory, an application processor chip such as a central processor (for example, a central processing unit (CPU)), a graphics processor (for example, a graphics processing unit (GPU)), a digital signal processor, a cryptographic processor, a microprocessor, or a microcontroller, and a logic chip such as an m analog-to-digital converter or an application-specific integrated circuit (ASIC). However, the chip-related components 1020 are not limited thereto, and may include other types of chip-related components. In addition, the chip-related components 1020 may be combined with each other. The chip-related components 1020 may be in the form of a package including the above-described chip or electronic component.

The network-related components 1030 may include protocols such as wireless fidelity (Wi-Fi) (Institute of Electrical And Electronics Engineers (IEEE) 802.11 family or the like), worldwide interoperability for microwave access (WiMAX) (IEEE 802.16 family or the like), IEEE 802.20, long term evolution (LTE), evolution data only (Ev-DO), high speed packet access+ (HSPA+), high speed downlink packet access+ (HSDPA+), high speed uplink packet access+ (HSUPA+), enhanced data GSM environment (EDGE), global system for mobile communications (GSM), global positioning system (GPS), general packet radio service (GPRS), code division multiple access (CDMA), time division multiple access (TDMA), digital enhanced cordless telecommunications (DECT), Bluetooth®, 3G, 4G, and 5G protocols, and any other wireless and wired protocols, designated after the above-described protocols. However, the network-related components 1030 are not limited thereto, and may also include a variety of other wireless or wired standards or protocols. In addition, the network-related components 1030 may be combined with each other, together with the chip-related components 1020 described above.

The other components 1040 may include a high frequency inductor, a ferrite inductor, a power inductor, ferrite beads, a low temperature co-fired ceramic (LTCC), an electromagnetic interference (EMI) filter, a multilayer ceramic capacitor (MLCC), or the like. However, the other components 1040 are not limited thereto, and may also include passive components used for various other purposes, or the like. In addition, the other components 1040 may be combined with each other, together with the chip-related components 1020 or the network-related components 1030 described above.

Depending on a type of the electronic device 1000, the electronic device 1000 may include other components that may be or may not be physically or electrically connected to the mainboard 1010. The other components may include, for example, a camera module 1050, an antenna module 1060, a display 1070, a battery 1080, and the like. However, the other components are not limited thereto, and may be an audio codec, a video codec, a power amplifier, a compass, an accelerometer, a gyroscope, a speaker, a mass storage unit (for example, a hard disk drive), a compact disk (CD), a digital versatile disk (DVD), or the like. The other components may also include other components used for various purposes depending on the type of electronic device 1000.

The electronic device 1000 may be a smartphone, a personal digital assistant (PDA), a digital video camera, a digital still camera, a network system, a computer, a monitor, a tablet PC, a laptop PC, a netbook PC, a television, a video game machine, a smartwatch, an automotive component, or the like. However, the electronic device 1000 is not limited thereto, and may be any other electronic device to process data.

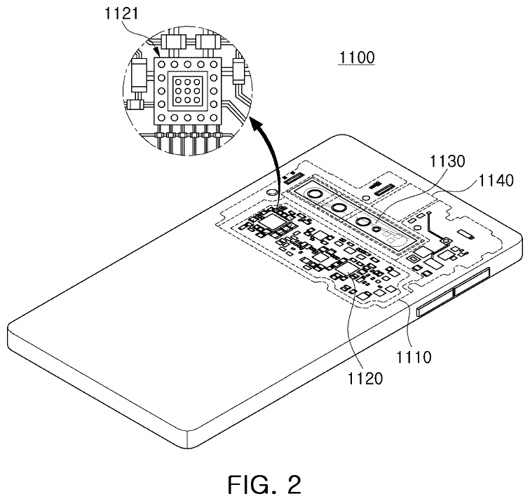

FIG. 2 is a schematic perspective view of an example of an electronic device.

Referring to FIG. 2, an electronic device may be, for example, a smartphone 1100. The motherboard 1110 may be accommodated in the smartphone 1100, and various electronic components 1120 may be physically and/or electrically connected to the motherboard 1110. In addition, other electronic components that may be or may not be physically and/or electrically connected to the motherboard 1110 may be accommodated therein, such as a camera module 1130 and/or a speaker 1140. A portion of the electronic components 1120 may be the chip-related components described above, for example, a component package 1121, but the present disclosure is not limited thereto. The component package 1121 may be in the form of a printed circuit board on which electronic components including active components and/or passive components are surface-mounted. The electronic device is not necessarily limited to the smartphone 1100, and may be other electronic devices, as described above.

### Printed Circuit Board

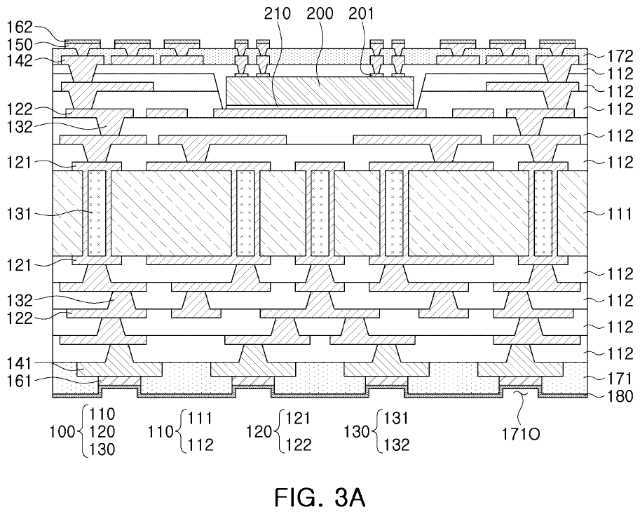

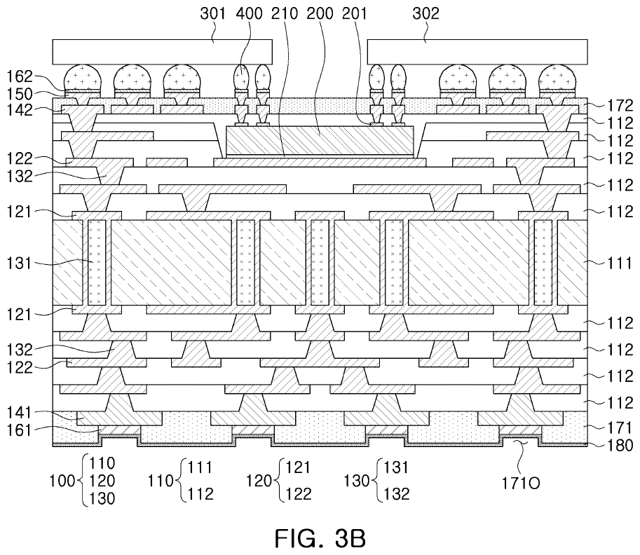

FIGS. 3A and 3B are example schematic cross-sectional views of a printed circuit board.

Referring to FIG. 3A, a printed circuit board according to an example may include a wiring portion 100 including one or more insulating layers 110, one or more wiring layers 120 respectively disposed on or in the one or more insulating layers 110, a first pad 141 disposed on a lowermost insulating layer, among the one or more insulating layers 110, and a second pad 142 disposed on an uppermost insulating layer, among the one or more insulating layers 110. In addition, the printed circuit board according to an example may include a first solder resist layer 171 disposed on a lower side of the wiring portion 100 to cover at least a portion of the first pad 141, the first solder resist layer having a first opening 1710, a first surface treatment layer 161 disposed on at least a portion of the first pad 141, a barrier layer 180 disposed on the first solder resist layer 171, a second solder resist layer 172 disposed on an upper side of the wiring portion 100, and a metal post 150 disposed on the second solder resist layer 172. The printed circuit board may further include a second surface treatment layer 162 disposed on the metal post 150. In this case, the barrier layer 180 may include an inorganic oxide film. A thickness of the barrier layer 180 may be less than a thickness of the first pad 141, and may be less than a thickness of the first surface treatment layer 161.

The printed circuit board according to an example may include the barrier layer 180 on the first solder resist layer 171, such that at least a portion of the first surface treatment layer 161 disposed on the first pad 141 may be covered by the barrier layer 180. The first surface treatment layer 161 may be covered by the barrier layer 180, such that galvanic corrosion caused by etching may not occur in an operation of disposing the metal post 150 on the second pad 142.

Galvanic corrosion may occur when two metals having different electrochemical properties, such as standard reduction potential, are exposed to a corrosive solution in a state of being electrically connected to each other. The metal that is more active or has a lower standard reduction potential value may corrode during galvanic corrosion. The first surface treatment layer 161 may include gold (Au) on an outermost side thereof, and the second pad 142 may include copper (Cu). In an operation of pretreating the second pad 142 through a second opening 1720 of the second solder resist layer 172 to dispose the metal post 150 on the second pad 142, an etching solution for soft etching may be simultaneously exposed onto the second pad 142 and the first surface treatment layer 161. Accordingly, the second pad 142 including copper (Cu) having a relatively low standard reduction potential may act as an anode, and the first surface treatment layer 161 including gold (Au) having a relatively high standard reduction potential may act as a cathode, causing galvanic corrosion between the second pad 142 and the first surface treatment layer 161. More specifically, galvanic corrosion may occur in the second pad 142, causing defects in the second pad 142, and defects in the metal post 150 disposed on the second pad 142. The metal materials of the first surface treatment layer 161 and the second pad 142 are not necessarily limited thereto, and all cases may be included in which galvanic corrosion may occur between the first surface treatment layer 161 and the second pad 142 due to different standard reduction potentials.

As described above, in the printed circuit board according to an example, after the first surface treatment layer 161 is disposed on the first pad 141, the barrier layer 180 may be disposed on the first solder resist layer 171, thereby preventing the second pad 142 and the first surface treatment layer 161 from being simultaneously exposed to the etching solution during the operation of pretreating the second pad 142. More specifically, the barrier layer 180 may be conformally disposed along a lower surface of the first surface treatment layer 161, an inner wall of the first opening 1710 disposed in the first solder resist layer 171, and a lower surface of the first solder resist layer 171, thereby preventing galvanic corrosion of the second pad 142. The barrier layer 180 may include a thin oxide film, but the present disclosure is not necessarily limited thereto.

The printed circuit board according to an example may prevent galvanic corrosion of the second pad 142, such that no defects occur when the second pad 142 and the metal post 150 are designed to have a fine pitch. Accordingly, it may be advantageous to connect a component having a fine pitch, such as a semiconductor chip or the like, to an upper side of the wiring portion 100.

The insulating layer 110 may include one or more insulating layers. For example, the insulating layer 10 may include a first insulating layer 111 as a core layer, and a second insulating layer 112 as a build-up insulating layer. The insulating layer 110 may include an insulating material. The insulating material may include a thermosetting resin such as an epoxy resin, a thermoplastic resin such as polyimide, or a material including an inorganic filler, an organic filler, and/or a glass fiber (glass cloth, and/or glass fabric), together with the above-described resins. The insulating material may have either/both photosensitive properties and/or non-photosensitive properties. For example, the insulating material of the insulating layer 110 may be an insulating material of an Ajinomoto Build-up Film (ABF), but the present disclosure is not limited thereto, and may include prepreg (PPG), resin coated copper (RCC), photoimageable dielectric (PID), FR-4, bismaleimide triazine (BT), or the like. However, the present disclosure is not limited thereto, and other materials having excellent rigidity, such as a glass material or the like, may be used, as necessary.

The wiring layer 120 may include one or more wiring layers, and may include a first wiring layer 121 disposed on the first insulating layer 111, and a second wiring layer 122 as a build-up wiring layer disposed on or in the second insulating layer 112.

The wiring layer 120 may include a metal material. The metal material may include copper (Cu), aluminum (Al), silver (Ag), tin (Sn), gold (Au), lead (Pb), titanium (Ti), or alloys thereof. The metal material may preferably include copper (Cu), but the present disclosure is not limited thereto, and the first wiring layer 121 and the second wiring layer 122 may include different metal materials. The wiring layer 120 may perform various functions depending on a design thereof. For example, the wiring layer 120 may include a signal pattern, a power pattern, a ground pattern, and the like, but the present disclosure is not limited thereto, and may function as a pad on which an electronic component and a chip are mounted, or as a stopper for forming a cavity. Each of the above-described patterns may have various forms such as a line, a plane, a pad, and the like. The wiring layers 120 may have different pitches depending on functions thereof. When the wiring layers 120 require a high-density fine pitch for connection to a connection structure or a semiconductor chip, a distance between the wiring layers 120 may decrease. When the wiring layers 120 perform signal connection, the distance between the wiring layers 120 may increase.

The wiring layer 120 may be disposed using one of a semi-additive process (SAP), a modified semi-additive process (MSAP), tenting (TT), or a subtractive process, but the present disclosure is not limited thereto. The wiring layer 120 may include an electroless plating layer (or chemical copper) as a seed layer, and an electrolytic plating layer (or electrolytic copper) as a plating layer, but the present disclosure is not limited thereto. A sputtering layer may be disposed instead of chemical copper as an electroless plating layer. Copper foil may be further included, as necessary.

The wiring portion 100 of the printed circuit board according to an example may include a via layer 130 connecting the wiring layers 120 to each other. The via layer 130 may include one or more via layers, and may include a first via layer 131 as a through-via layer passing through the first insulating layer 111, and a second via layer 132 as a build-up via layer passing through at least a portion of the second insulating layer 112.

The first via layer 131 may include a metal layer disposed on a wall surface of a through-hole passing through the first insulating layer 111, and a plug filling the metal layer. The metal layer may include copper (Cu), aluminum (Al), silver (Ag), tin (Sn), gold (Au), nickel (Ni), lead (Pb), titanium (Ti), or alloys thereof, and may preferably include copper (Cu), but the present disclosure not limited thereto. The plug may include ink having a composition that includes an insulating material. The metal layer may include an electroless plating layer (or chemical copper) and an electrolytic plating layer (or electrolytic copper), but the present disclosure not limited thereto. A sputtering layer may be disposed instead of or in addition to the electroless plating layer. The first via layer 131 may perform various functions depending on a design thereof. For example, a ground via, a power via, a signal via, and the like may be included.

The second via layer 132 may include a micro via. The micro via may be a filled via filling a via hole, or a conformal via disposed along a wall surface of the via hole. The micro via may be disposed as a stacked-type via and/or a staggered-type via. The second via layer 132 may include a metal. The metal may include copper (Cu), aluminum (Al), silver (Ag), tin (Sn), gold (Au), nickel (Ni), lead (Pb), titanium (Ti), or alloys thereof, and may preferably include copper (Cu), but the present disclosure not limited thereto. The second via layer 132 may include an electroless plating layer (or chemical copper) and an electrolytic plating layer (or electrolytic copper), but the present disclosure is not limited thereto. A sputtering layer may be disposed instead of or in addition to the electroless plating layer. The second via layer 132 may perform various functions depending on a design thereof. For example, a ground via, a power via, a signal via, and the like may be included.

The printed circuit board according to an example may include a first pad 141 on a lower side of the wiring portion 100. The first pad 141 may be disposed on or in a lowermost insulating layer, among the second insulating layers 112. In FIG. 3A, it is illustrated that the first pad 141 is disposed on the second insulating layer 112 and protruding from a lower side of the second insulating layer 112, but the present disclosure is not necessarily limited thereto. The first pad 141 may have a coreless structure in which the first pad 141 is embedded in the lower side of the second insulating layer 112. The first pad 141 may be connected to at least a portion of the second wiring layer 122 through one via layer, among the second via layers 132.

The first pad 141 may include a metal material, and the metal material may include copper (Cu), aluminum (Al), silver (Ag), tin (Sn), gold (Au), nickel (Ni), lead (Pb), titanium (Ti), and/or alloys thereof, and may preferably include copper (Cu), but the present disclosure is not limited thereto. The first pad 141 may be disposed on a lowermost side of the printed circuit board, and may function as a connection pad, such that a lower surface of the printed circuit board is connected to other components such as a main board and the like. However, the present disclosure is not limited thereto, and the first pad 141 may function as a means for connection to a component having a fine pitch, such as a semiconductor chip, and the pitch may be designed in various manners depending on a function thereof. The first pad 141 may perform various functions depending on a design thereof. For example, the first pad 141 may include a ground pad, a power pad, a signal pad, and the like. Here, the signal pad may include a pad for electrical connection of various signals other than a ground signal, a power signal, and the like, for example, a data signal and the like.

The printed circuit board according to an example may include a second pad 142 on an upper side of the wiring portion 100. The second pad 142 may be disposed on or in an uppermost insulating layer, among the second insulating layers 112. In FIG. 3A, it is illustrated that the second pad 142 is disposed on the second insulating layer 112 and protruding toward an upper side of the second insulating layer 112. However, the present disclosure is not necessarily limited thereto, and the second pad 142 may also be embedded in the second insulating layer 112. In this case, the second pad 142 may have a pad structure having a pitch finer than that of the first pad 141. As a non-limiting example, a structure in which the second pad 142 is embedded in the second insulating layer 112 may be preferable to a structure in which the first pad 141 is embedded in the second insulating layer 112. The second pad 142 may be connected to at least a portion of the second wiring layer 122 through one via layer 130, among the second via layers 132.

The second pad 142 may include a metal material, and the metal material may include copper (Cu), aluminum (Al), silver (Ag), tin (Sn), gold (Au), nickel (Ni), lead (Pb), titanium (Ti), and/or alloys thereof, and may preferably include copper (Cu), but the present disclosure is not limited thereto. The second pad 142 may be disposed on an uppermost side of the printed circuit board, may be a region in which an electronic component and a chip are mounted, and may be connected to a circuit pattern to perform signal connection with other pads. The second pad 142 may perform various functions depending on a design thereof. For example, the second pad 142 may include a ground pad, a power pad, a signal pad, and the like. The signal pad may include a pad for electrical connection of various signals other than a ground signal, a power signal, and the like, for example, a data signal and the like. When the second pad 142 requires a high-density fine pitch to mount a semiconductor chip or the like, a distance between the second pads 142 may decrease. When an electronic component is mounted, the distance between the second pads 142 may increase. Additionally, the distance between the second pads 142 after disposing a semiconductor chip or the like may further decrease as other components such as the connection structure 200 and the like are disposed.

The first pad 141 and the second pad 142 may be formed using one of an SAP, an MSAP, TT, or a subtractive process, but the present disclosure is not limited thereto, and may be formed using a method that could be used by those skilled in the art.

The printed circuit board according to an example may include a first solder resist layer 171 and a second solder resist layer 172 disposed on the lower and upper sides of the wiring portion 100, respectively. The first solder resist layer 171 is disposed on the lowest insulating layer of the second insulating layer 112, and the second solder resist layer 172 is disposed on the uppermost side of the second insulating layer 112. It may be placed on an insulating layer.

The first solder resist layer 171 and the second solder resist layer 172 may be respectively disposed on an outermost side of the printed circuit board to externally protect the printed circuit board. The first solder resist layer 171 and the second solder resist layer 172 may use a known solder resist. The first solder resist layer 171 and the second solder resist layer 172 may include a thermosetting resin and an inorganic filler dispersed in the thermosetting resin, but may not include a glass fiber. An insulating resin may be a photosensitive insulating resin, and a filler may be an inorganic filler and/or an organic filler, but the present disclosure is not limited thereto, and other polymer materials may be used. When the photosensitive insulating resin is used as a solder resist layer, it may be advantageous to dispose a fine opening, but the present disclosure it is not limited thereto, and a fine opening may also be formed with a UV laser while the solder resist layer includes a non-photosensitive insulating resin.

The first solder resist layer 171 may have a first opening 1710, and at least a portion of the first pad 141 may be exposed by the first opening 1710 . . . . A portion of the first pad 141 being exposed by the first opening 1710 may mean that a portion of the first pad 141 may be connected other components due to the first solder resist layer 171 not covering a portion of the first pad 141 in addition to the first pad 141 being exposed to the outside of the printed circuit board.

In FIG. 3A, it is illustrated that the first opening 1710 of the first solder resist layer 171 exposes a portion of an upper surface of the first pad 141, but the first solder resist layer 171, the first opening 1710, and the first pad are not limited to being aligned in a solder mask defined (SMD) form, and may be aligned in a non-solder mask defined (NSMD) form, or the like. A relationship between the first pad 141 and the first solder resist layer 171 is not limited to that illustrated in the drawing. When aligned in the NSMD form, a width of the first opening 1710 of the first solder resist layer 171 may be formed to be wider than a width of the first pad 141, the upper surface of the first pad 141 may be exposed by the solder resist layer 171, and a side surface of the first pad 141 may also be exposed by the first solder resist layer 171.

The second solder resist layer 172 may cover at least a portion of the second pad 142. In addition, the metal post 150 may pass through a portion of the second solder resist layer 172, and may protrude from the second solder resist layer 172. The metal post 150 protruding further than the second solder resist layer 172 may mean that an upper surface of the metal post 140 may be positioned to be higher than an upper surface of the solder resist layer 160.

The second solder resist layer 172 may also expose at least a portion of the second pad 142 through the second opening, and the second opening may be filled by the metal post 150. In this case, in a region in which the metal post 150 and the second pad 142 are in contact with each other, a width of a lower end of the metal post 150 may be formed to be narrower than a width of the second pad 142. As described above, a width of the second opening formed in the second solder resist layer 172 may also have various widths in the same manner as the width of the first opening 1710, such that a width of the metal post 150 may be formed to be wider than the width of the second pad 142.

The printed circuit board according to an example may further include a first surface treatment layer 161 disposed on at least a portion of the first pad 141. The first surface treatment layer 161 may include one metal among nickel (Ni), palladium (Pd), and gold (Au), and a plurality of layers including the above-described metal may be implemented. For example, the first surface treatment layer 161 may be at least a portion of an electroless nickel electroless palladium immersion gold (ENEPIG) structure, or may be at least a portion of an electroless nickel immersion gold (ENIG) structure. In this case, the first surface treatment layer 161 may include a gold (Au) plating layer on an outermost side thereof. The gold (Au) plating layer may be formed by performing electroless plating, and preferably by performing substitution plating. The first surface treatment layer 161 may improve adhesion and signal transmission between the first pad 141 and a connection member. In FIG. 3A, it is illustrated that the first surface treatment layer 161 is implemented as a single layer, but the present disclosure is not limited thereto, and the first surface treatment layer 161 may be implemented as a plurality of metal layers, as described above. However, the plurality of metal layers may not have clear boundaries therebetween.

The first surface treatment layer 161 may cover at least a portion of the first pad 141. The first surface treatment layer 161 may cover a portion of the first pad 141 exposed by the first opening 1710 of the first solder resist layer 171. In this case, the first surface treatment layer 161 may be disposed after the first opening 1710 is formed in the first solder resist layer 171. Accordingly, when a shape of the first opening 1710 has an NSMD structure unlike that illustrated FIG. 3A, the first surface treatment layer 161 may be disposed to cover a side surface of the first pad 141.

The first surface treatment layer 161 may include a gold (Au) plating layer on the outermost side thereof. Galvanic corrosion may occur in the second pad 142.

The printed circuit board according to an example may include a barrier layer 180 disposed on the first solder resist layer 171. Referring to FIG. 3A, the barrier layer 180 may be disposed on a lower surface of the first solder resist layer 171, and may be disposed along an inner wall of the first opening 1710 and at least a portion of the first surface treatment layer 161. As the barrier layer 180 is disposed to cover a portion of the first surface treatment layer 161, the first surface treatment layer 161 may not be externally exposed. That is, as the barrier layer 180 covers the first surface treatment layer 161, galvanic corrosion may be prevented during a process of pretreating the second pad 142 before the metal post 150 is disposed. In particular, the barrier layer 180 may cover the gold (Au) plating layer disposed on the outermost side of the first surface treatment layer 161.

The barrier layer 180 may include an oxide film including an inorganic oxide. The inorganic oxide may be an alumina film, for example, an oxide film including Al₂O₃, but the present disclosure is not limited thereto, and may be an oxide film including TiO₂, ZnO, SiO₂, or the like. The barrier layer 180 may be a coating layer disposed using a thin film deposition method, such as an atomic layer deposition (ALD) method or a molecular vapor deposition (MVD) method. In this case, a thin oxide film may be disposed using a deposition method. As a non-limiting example, the barrier layer 180 may include a thin film having a thickness of less than 100 nm, for example, a thickness of about 1 nm to 10 nm. The thickness of the barrier layer 180 may be less than a thickness of the first pad 141, and may be less than a thickness of the first surface treatment layer 161. The barrier layer 180 may have a nano-scale thickness, whereas the first pad 141 and the first surface treatment layer 161 may have a micro-scale thickness. Accordingly, the thickness of the barrier layer 180 may be thinner than the thickness of the first pad 141 and the thickness of the first surface treatment layer 161.

As the barrier layer 180 includes a thin inorganic oxide film, the first pad 141 and the first surface treatment layer 161 may be electrically disconnected from other components connected to a lower portion of the printed circuit board. For example, when the printed circuit board is mounted on a motherboard through a connection metal, the barrier layer 180 may be positioned between the first pad 141 and the first surface treatment layer 161 and the connection metal. However, when the oxide film included in the barrier layer 180 is a metal oxide, a connection metal including a metal material, having an element the same as that of the metal oxide of the barrier layer 180, may be used. For example, when the barrier layer 180 includes Al₂O₃, a connection metal including aluminum (Al) may be selected. In this case, in an operation in which the connection metal is disposed, an aluminum (Al) element, among Al₂O₃ of the barrier layer 180, may diffuse, and accordingly a portion of the oxide film of the barrier layer 180 is removed from a portion of the barrier layer 180 in contact with the connection metal. As a result, the first pad 141 and the first surface treatment layer 161 may be electrically connected to other components through the connection metal. Accordingly, in a case in which the printed circuit board is electrically connected to other components, such as a motherboard and the like, through the connection metal, even when a portion of the barrier layer 180 is not confirmed in a region in which the connection metal and the barrier layer 180 are in contact with each other, such a phenomenon may be caused by diffusion, and thus may fall within the scope of the disclosure.

The printed circuit board according to an example may further include a metal post 150 disposed on at least a portion of the second pad 142. The metal post 150 may be disposed on the second pad 142 to pass through at least a portion of the second solder resist layer 172. The metal post 150 may include a metal material. The metal material may be copper (Cu), aluminum (Al), silver (Ag), tin (Sn), gold (Au), lead (Pb), titanium (Ti), or alloys thereof. The metal material may preferably include copper (Cu), but the present disclosure is not limited thereto. The metal post 150 may be a region in which an electronic component and a chip are mounted, and may be a component protruding to facilitate smooth connection when an electronic component and a chip are mounted on the second pad 142. The metal post 150 may perform various functions depending on a design of the second pad 142. The metal post 140 may electrically exchange a signal with the pad 120.

When the second pad 142 requires a high-density fine pitch to mount a semiconductor chip or the like, a distance between the second pads 142 and/or a distance between the metal posts 150 may decrease. As the metal post 150 is disposed on the second pad 142, even when a semiconductor chip having a fine pitch is mounted, a short circuit may be less likely to occur in the connection member 170 disposed between the semiconductor chip and the metal post 150, and defects in which the semiconductor chip is detached may be reduced. In addition, as the metal post 150 is disposed on the second pad 142, adhesion may be secured through the metal post 150 rather than a structure in which a connection member 400 is directly disposed on the second pad 142, thereby improving the reliability of the printed circuit board.

The metal post 150 may be disposed using one of an SAP, an MSAP, TT, or a subtractive process, but the present disclosure is not limited thereto, and may be disposed using a method that could be used by those skilled in the art.

The printed circuit board according to an example further include a second surface treatment layer 162 disposed on at least a portion of the metal post 150. The second surface treatment layer 162 may include one metal among nickel (Ni), palladium (Pd), and gold (Au), and a plurality of layers including the above-described metal may be implemented. For example, the second surface treatment layer 162 may be at least a portion of an electroless nickel electroless palladium immersion gold (ENEPIG) structure, or may be at least a portion of an electroless nickel immersion gold (ENIG) structure. The second surface treatment layer 162 is not limited thereto, and may include an organic solder passivation (OSP) structure including an organic material. The second surface treatment layer 162 may improve adhesion and signal transmission between the metal post 150 and a connection member. In FIG. 3A, it is illustrated that the second surface treatment layer 162 is implemented as a single layer, but the present disclosure is not limited thereto, and the second surface treatment layer 162 may be implemented as a plurality of metal layers, as described above.

The second surface treatment layer 162 may cover at least a portion of the metal post 150. In FIG. 3A, it is illustrated that the second surface treatment layer 162 covers an upper surface of the metal post 150, but it is not necessarily limited thereto, and may be disposed to further cover an exposed side surface of the metal post 150.

The printed circuit board according to an example may further include a connection structure 200 and an adhesive layer 210. The connection structure 200 may be connected to an electronic component such as a semiconductor chip or the like. For example, the connection structure 200 may have a bridge structure. The connection structure 200 may include a body with a pattern implemented on an insulating material, and may include a connection portion 201 for connection to the wiring portion 100. The connection structure 200 may be an organic substrate or a silicon bridge with a circuit implemented on a silicon wafer. The present disclosure is not limited thereto, and the connection structure 200 may be a single semiconductor chip embedded in the wiring portion 100 of the printed circuit board.

The connection structure 200 may be disposed in a cavity passing through at least a portion of the second insulating layer 112, and may be embedded by the second insulating layer 112. The connection structure 200 may further include an adhesive layer 210 such that the connection structure 200 is mounted in the cavity. The structure of the connection structure 200 and the mounting method of the connection structure 200 could be used by those skilled in the art.

Referring to FIG. 3B, the printed circuit board according to an example may further include semiconductor chips 301 and 302 disposed on the metal post 150, and a connection member 400 connecting the metal post 150 and the semiconductor chips 301 and 302 to each other.

The semiconductor chips 301 and 302 may be integrated circuits (ICs) in which hundreds to millions of circuits are integrated into a single chip. Each of the ICs may be a processor chip, specifically, an application processor (AP), such as a central processor (for example, a CPU), a graphics processing unit (for example, a GPU), a field programmable gate array (FPGA), a digital signal processor, a cryptographic processor, a microprocessor, or a microcontroller, but the present disclosure is not limited thereto, and may be a logic chip such as an analog-digital converter or an application-specific (ASIC) memory controller (MC) chip, or may be a memory chip such as a dynamic random access memory (DRAM) chip, a static random access memory (SRAM) chip, a flash memory chip, a phase-change random access memory (PRAM) chip, a magnetic random access memory (MRAM) chip, a resistive random access memory (RRAM) chip, an electrically erasable and programmable read-only memory (EEPROM) chip, or a high bandwidth memory (HBM) chip, and the above-described chips may be disposed in combination with each other.

The semiconductor chip 200 may include a body and a connection pad. A surface of the semiconductor chip 200 on which the connection pad for connection to the metal post 150 is disposed may be an active surface, and an opposite surface of the semiconductor chip 200 may be an inactive surface, but the present disclosure is limited thereto. However, connection may be performed through both surfaces. In some cases, the semiconductor chip 200 may have a three-dimensional structure. The semiconductor chips 301 and 302 may be disposed on an active wafer. In this case, silicon (Si), germanium (Ge), gallium arsenide (GaAs), or the like may be used as a base material included in the body. Various circuits may be formed in the semiconductor chips 301 and 302, and at least some circuits, among the above-described circuits, may be connected to the connection pad.

The connection member 400 may be made of a conductive material, for example, solder, but the material of the connection member 400 is not particularly limited thereto. In addition, a connection method of the connection member 400 is not limited thereto, and may include a land, a ball, a pin, and the like. In addition, the connection member 400 may be made of multiple layers or a single layer. When made of multiple layers, the connection member 610 may include a copper pillar and solder. When made of a single layer, the connection member 610 may include tin-silver solder or copper, but the present disclosure is not limited thereto.

In FIG. 3B, it is illustrated that two semiconductor chips 301 and 302 are disposed on the printed circuit board, but the present disclosure is not limited thereto. In particular, it is illustrated that the semiconductor chips 301 and 302 are connected to each other in a die-to-die manner with the connection structure 200 interposed therebetween, but the present disclosure is not necessarily limited. The number and arrangement of the semiconductor chips 301 and 302, and the number and arrangement of the connection members 400, and a distance between the connection members 400 are not particularly limited, and may be sufficiently modified by those skilled in the art depending on a design thereof.

The printed circuit board according to an example is not limited to the components illustrated in FIGS. 3A and 3B, and may further include other components in some cases. That is, the printed circuit board may further include a component that could be used by those skilled in the art.

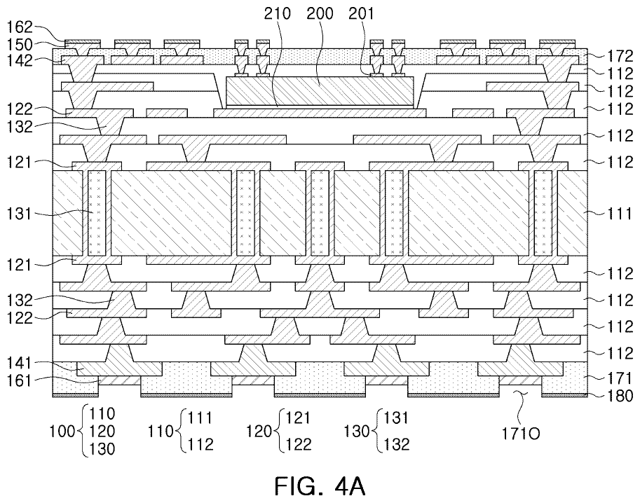

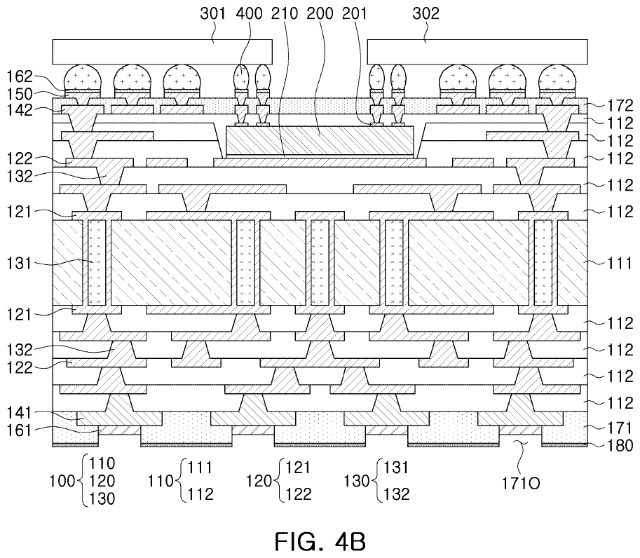

FIGS. 4A and 4B are schematic cross-sectional views of a printed circuit board according to another example.

Referring to FIGS. 4A and 4B, in the printed circuit board according to another example, a barrier layer 180 may have a different arrangement, as compared to the printed circuit board according to an example.

The barrier layer 180 of the printed circuit board according to another example may not be disposed in a first opening 1710, and may not be disposed on a first surface treatment layer 161. Such a result may be a result of performing an operation of removing a portion of the barrier layer 180 after preventing galvanic corrosion in an operation of disposing a metal post 150 using the barrier layer 180. Such a result may be a result of performing an operation of selectively removing a portion of the barrier layer 180, such as dry etching, such that the barrier layer 180 does not cover the first opening 1710 and the first surface treatment layer 161. The barrier layer 180 may include an oxide film.

Accordingly, in a case in which the barrier layer 180 is not disposed on the first surface treatment layer 161, when the printed circuit board and other components are coupled to each other, the first pad 141 may be more easily connected through the first surface treatment layer 161.

A configuration of the printed circuit board according to an example, excluding an arrangement and a shape of the barrier layer 180, may be applied to the printed circuit board according to another example, and thus a repeated description related thereto will be omitted.

### Method of Manufacturing Printed Circuit Board

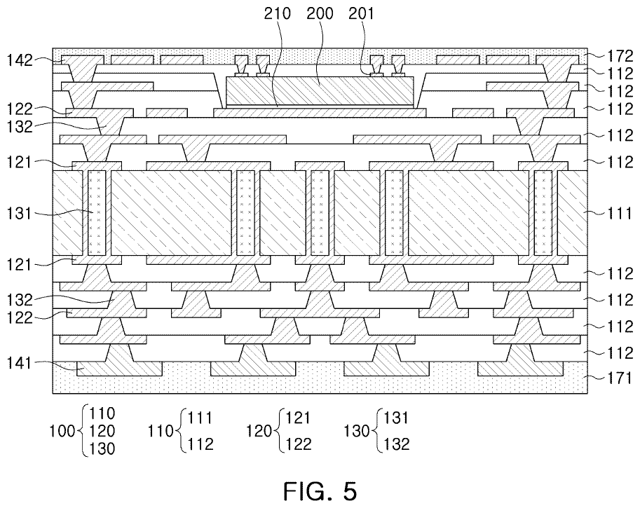

FIGS. 5 to 15 are schematic cross-sectional views of a method of manufacturing a printed circuit board according to an example.

A method of manufacturing a printed circuit board according to an example may include an operation of preparing a wiring portion 100, an operation of disposing a first solder resist layer 171 on a lower side of the wiring portion 100, an operation of disposing a second solder resist layer 172 on an upper side of the wiring portion 100, an operation of disposing a first opening 1710 in the first solder resist layer such that at least a portion of the first pad 141 is exposed, an operation of disposing a first surface treatment layer 161 on an exposed portion of the first pad 141, an operation of disposing a barrier layer on the first solder resist layer, and an operation of disposing a metal post on a second pad. In this case, the method of manufacturing the printed circuit board according to an example may not include an operation of entirely removing barrier layer, and the barrier layer 180 may remain on the first solder resist layer 171 in the printed circuit board.

Referring to FIG. 5, the wiring portion 100 may include one or more insulating layers 110, one or more wiring layers 120 disposed on or in the one or more insulating layers 110, a first pad 141 disposed on a lowermost insulating layer, among the one or more insulating layers 110, and a second pad 142 disposed on an uppermost insulating layer, among the one or more insulating layers 110. The operation of preparing the wiring portion 100 may include an operation of disposing a first wiring layer 121 on the first insulating layer 111, and an operation of disposing a second insulating layer 112 on the first insulating layer 111, and disposing a second wiring layer 122. The operation of preparing the wiring portion 100 may include an operation of disposing a first pad 141 and a second pad 142 on the second insulating layer 112 disposed on an outermost side of the first insulating layer 111, respectively. In this case, an operation of disposing the insulating layer 110 and the wiring layer 120 may be performed using a known build-up process.

The method of manufacturing the printed circuit board according to an example may further include an operation of forming a cavity passing through at least a portion of the second insulating layer 112, attaching and mounting a connection structure 200 using an adhesive layer 210, and embedding the connection structure 200 in the second insulating layer 112, but the present disclosure is not necessarily limited thereto.

The method may include the operation of disposing the first solder resist layer 171 on a lower side of the wiring portion 100, and the operation disposing the second solder resist layer 172 on an upper side of the wiring portion 100. The solder resist layers may be simultaneously disposed, but the present disclosure is not necessarily limited thereto. Any known method of disposing the first solder resist layer 171 and the second solder resist layer 172 may be used without limitation.

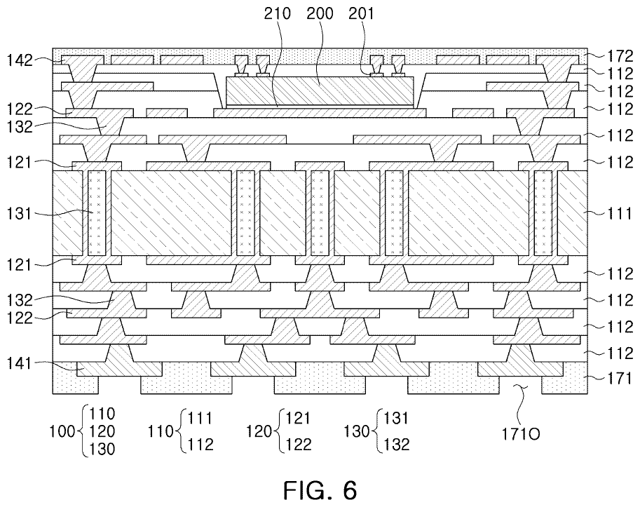

Referring to FIG. 6, the operation of forming the first opening 1710 in the first solder resist layer 171 may be performed. The first opening 1710 may be formed on the first pad 141, and at least a portion of the first pad 141 may be exposed through the first opening 1710. A shape of the first opening 1710 is not limited to the SMD structure illustrated in FIG. 6, and may have an NSMD structure, as described above in connection with the printed circuit board. Any known method of forming the first opening 1710 in the first solder resist layer 171 may be used without limitation.

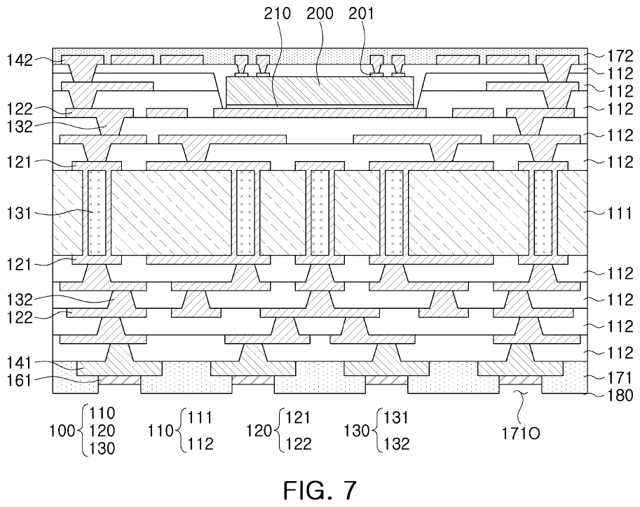

Referring to FIG. 7, an operation of disposing the first surface treatment layer 161 on at least a portion of the first pad 141 may be performed. The first surface treatment layer 161, including a plurality of metal layers, may be formed by repeatedly performing electroless plating as described above in connection with the printed circuit board, and the first surface treatment layer 161 may include a gold (Au) plating layer on an outermost side thereof.

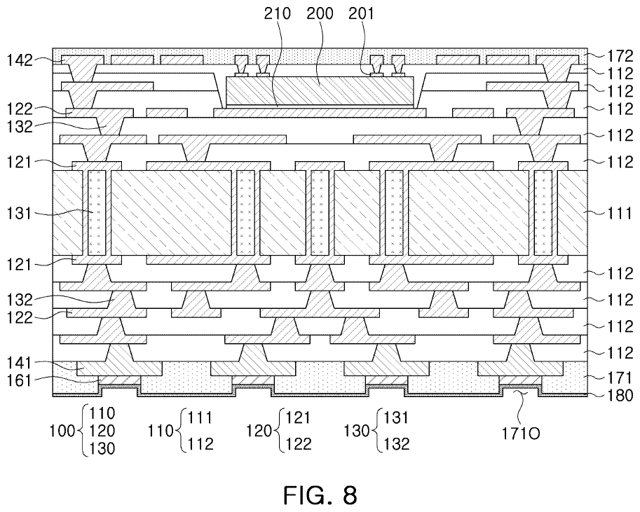

Referring to FIG. 8, an operation of disposing the barrier layer 180 on the first solder resist layer 171 may be included. The operation of disposing the barrier layer 180 may be performed using a thin film deposition method, such as an ALD method or an MVD method. The deposition method may correspond to a method having excellent step coverage, such that the barrier layer 180 may be disposed on a lower surface of the first solder resist layer 171, an inner wall of the first opening 1710, and a portion of the first surface treatment layer 161.

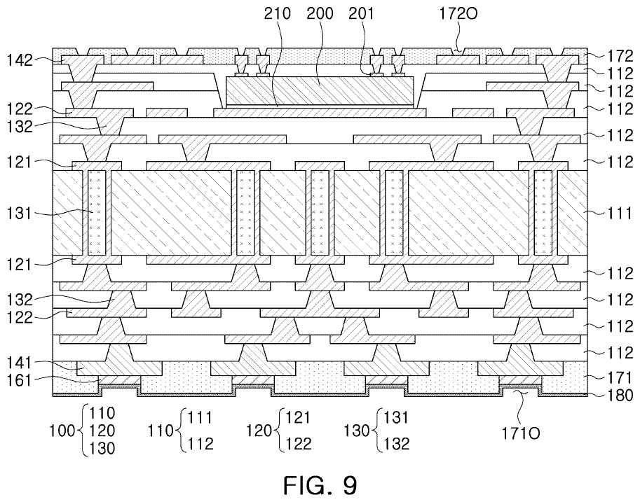

Referring to FIG. 9, an operation of disposing a second opening 1720 in the second solder resist layer 172 may be included. In this case, the second pad 142 may be exposed by the second opening 1720. A method of forming an opening in the second solder resist layer 172 may be performed using UV laser processing or the like, but the present disclosure is not necessarily limited thereto, and any known method of forming the second opening 1720 in the second solder resist layer 172 may be used without limitation. In this case, the second opening 1720 may be disposed using a physical method, and may have a downwardly tapered shape, but the present disclosure is not necessarily limited thereto.

Subsequently, pretreatment may be performed to dispose the metal post 150. As pretreatment, a desmear process of removing residue disposed on the second solder resist layer 172 may be performed, and soft etching may be performed to process an exposed surface of the second pad 142. When the printed circuit board is exposed to an etching solution to perform soft etching, an oxidation/reduction reaction may occur between the second pad 142 including copper (Cu) and the first surface treatment layer 161 including gold (Au), such that galvanic corrosion may occur in the second pad 142. However, the method of manufacturing the printed circuit board according to an example may include an operation of disposing the barrier layer 180 to cover the first surface treatment layer 161 before pretreatment is performed to dispose the metal post 150, such that the first surface treatment layer 161 may not be exposed to the etching solution. Accordingly, the second pad 142 may be protected from galvanic corrosion. As described above in connection with the printed circuit board, a metal material included in the second pad 142 and a metal material included in the first surface treatment layer 161 are not limited thereto.

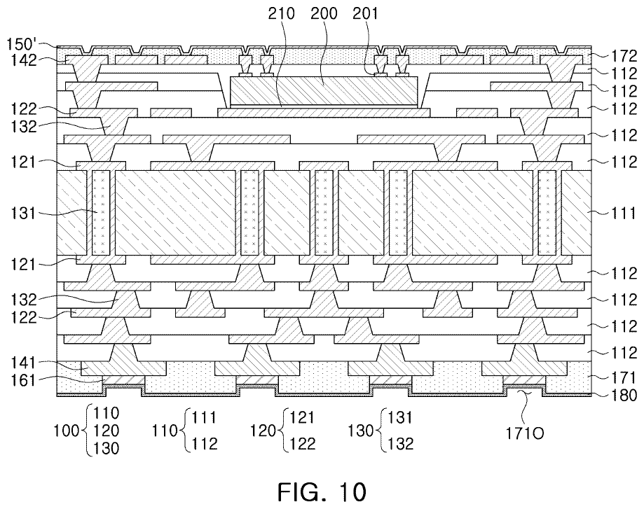

Referring to FIGS. 10 to 15, an operation of disposing the metal post 150 and the second surface treatment layer 162 on the second pad 142 may be performed.

Referring to FIG. 10, a seed layer 150′ may be disposed. The seed layer 150′ may be disposed by performing electroless plating, and may be disposed by performing chemical copper plating, but the present disclosure is not limited thereto, and may also be disposed by performing a sputtering method.

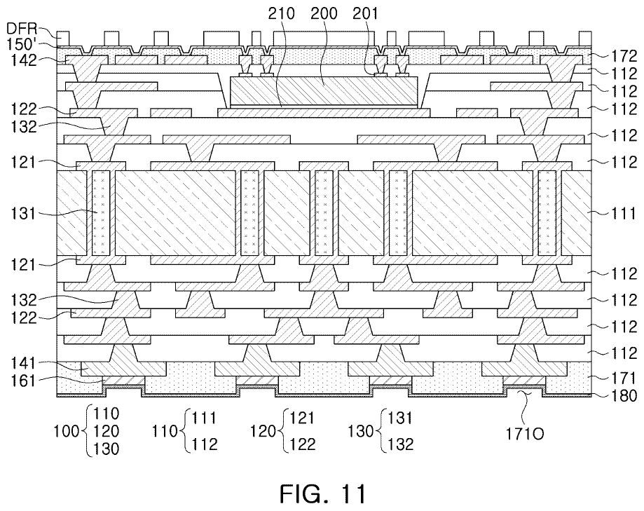

Referring to FIG. 11, a dry film resist DFR may be disposed. Before plating is performed, a plating resist may be disposed.

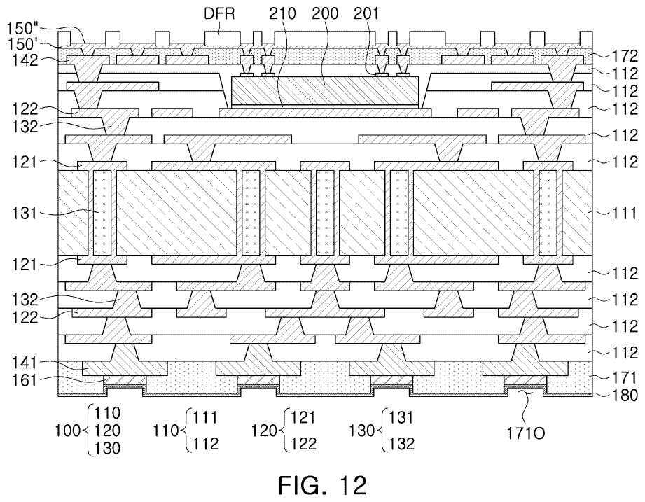

Referring to FIG. 12, a plating layer 150″ may be disposed. The plating layer 150″ may be disposed by performing electroplating using the seed layer 150″.

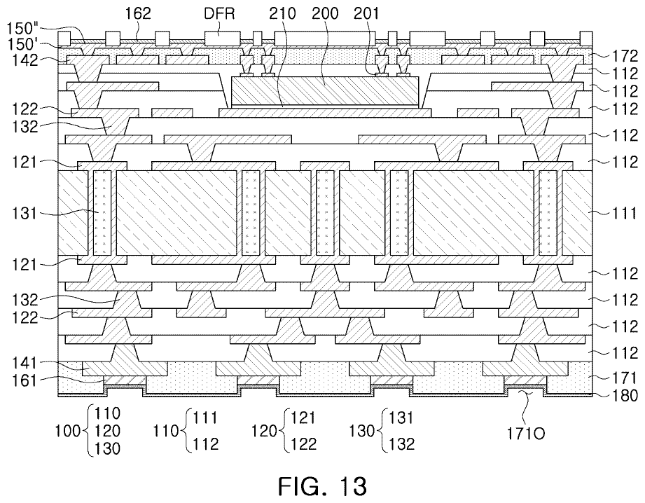

Referring to FIG. 13, the second surface treatment layer 162 may be disposed on the plating layer 150″ of the metal post 150.

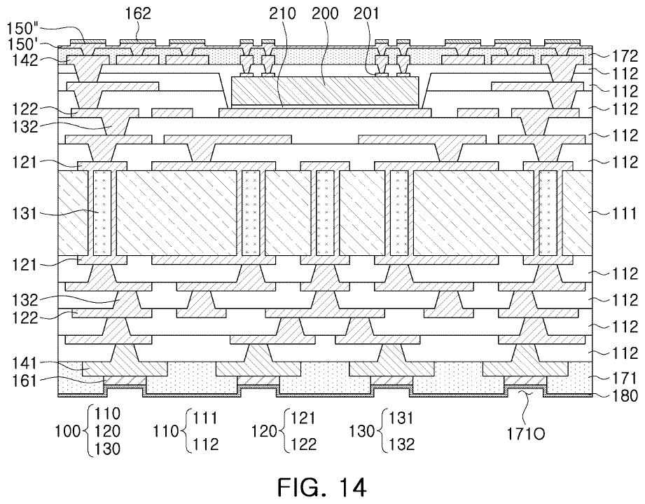

Referring to FIG. 14, a dry film resist DFR may be removed.

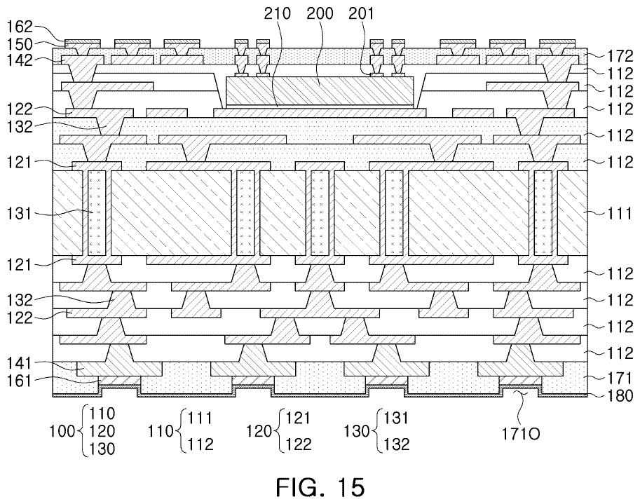

Referring to FIG. 15, the metal post 150 may be completed by removing a portion of the seed layer 150′.

The operation of disposing the metal post 150 is not limited thereto, and may be disposed using a method that could be used by those skilled in the art. The operation of disposing the metal post 150 and the second surface treatment layer 162 is not necessarily limited to those illustrated in FIGS. 10 to 15. In some cases, after the metal post 150 is completed, the operation of disposing the second surface treatment layer 162 may also be performed. In this case, the operation corresponding to FIG. 12 may be performed last.

The method of manufacturing the printed circuit board according to an example is not necessarily limited to those illustrated in FIGS. 5 to 15, and may be appropriately modified and changed, as necessary.

A method of manufacturing a printed circuit board according to another example may include an operation of removing a portion of the barrier layer 180 to expose the first surface treatment layer 161. The operation of removing a portion of the barrier layer 180 may be preferably performed after the operation of disposing the metal post 150 and the second surface treatment layer 162, but the present disclosure is not necessarily limited thereto.

As used herein, a cross-sectional shape may refer to a cross-sectional shape of an object when the object is vertically cut, or a cross-sectional shape of the object when the object is viewed in a side-view. In addition, a shape on a plane may be a shape of the object when the object is horizontally cut, or a planar shape of the object when the object is viewed in a top-view or a bottom-view.

As used herein, an upper side, an upper portion, the upper surface, or the like is used to refer to a direction toward a surface on which an electronic component is mountable based on a cross-section of a drawing for ease, and a lower side, a lower portion, a lower surface, or the like is used to refer to an opposite direction thereof.

However, the above-described directions are defined for ease of description. Thus, it should be understood that the scope of the claims is not particularly limited by the above-described directions.

As used herein, the term “connected” may not only refer to “directly connected” but also include “indirectly connected” by means of an adhesive layer, or the like. The term “electrically connected” may include both of a case in which components are “physically connected” and a case in which components are “not physically connected.” In addition, the terms “first,” “second,” and the like may be used to distinguish a component from another component, and may not limit a sequence and/or an importance, or others, in relation to the components. In some cases, a first component may be referred to as a second component, and similarly, a second component may be referred to as a first component without departing from the scope of the example embodiments.

As used herein, a process error or a positional deviation occurring in a manufacturing process, an error in measurement, and the like may be included. For example, “substantially perpendicular” may include not only “completely perpendicular,” but also “approximately perpendicular.” In addition, “substantially coplanar” may include not only “completely coplanar,” but also “approximately coplanar.”

As used herein, the same insulating material may mean not only the exact same insulating material, but also the same type of insulating material. Thus, compositions of insulating materials may be substantially the same, but specific composition ratios thereof may slightly vary.

As used herein, the term “an example embodiment” is provided to emphasize a particular feature, structure, or characteristic, and do not necessarily refer to the same example embodiment. In addition, the particular characteristics or features may be combined in any suitable manner in one or more example embodiments. For example, a context described in a specific example embodiment may be used in other example embodiments, even if it is not described in the other example embodiments, unless it is described contrary to or inconsistent with the context in the other example embodiments.

The terms used herein describe particular example embodiments only, and the present disclosure is not limited thereby. As used herein, singular forms “a,” “an,” and “the” are intended to include the plural forms as well, unless the context clearly indicates otherwise.

While example embodiments have been shown and described above, it will be apparent to those skilled in the art that modifications and variations could be made without departing from the scope of the present disclosure as defined by the appended claims.

What is claimed is:

1. A printed circuit board comprising:
a wiring portion including one or more insulating layers, one or more wiring layers respectively disposed on or in the one or more insulating layers, a first pad disposed on a lowermost insulating layer of the one or more insulating layers, and a second pad disposed on an uppermost insulating layer of the one or more insulating layers;
a first solder resist layer disposed on a lower side of the wiring portion to cover at least a portion of the first pad, the first solder resist layer having a first opening, on the first pad;
a second solder resist layer disposed on an upper side of the wiring portion to cover at least a portion of the second pad;
a first surface treatment layer disposed on at least a portion of the first pad; and
a barrier layer disposed on the first solder resist layer,
wherein a thickness of the barrier layer is less than a thickness of the first pad.

2. The printed circuit board of claim 1, wherein the barrier layer is disposed on a lower surface of the first solder resist layer.

3. The printed circuit board of claim 2, wherein the barrier layer is disposed along an inner wall of the first opening and at least a portion of the first surface treatment layer.

4. The printed circuit board of claim 1, wherein the first solder resist layer covers at least a portion of an upper surface of the first pad.

5. The printed circuit board of claim 1, wherein the second solder resist layer has a second opening disposed on the second pad.

6. The printed circuit board of claim 5, further comprising:
a metal post disposed in the second opening, the metal post disposed on at least a portion of the second pad.

7. The printed circuit board of claim 6, further comprising:
a second surface treatment layer disposed on the metal post.

8. The printed circuit board of claim 6, further comprising:
a first semiconductor chip disposed on the metal post; and
a connection member connecting the metal post and the first semiconductor chip to each other.

9. The printed circuit board of claim 1, wherein a thickness of the barrier layer is less than a thickness of the first surface treatment layer.

10. The printed circuit board of claim 9, wherein the thickness of the barrier layer is less than 100 nm.

11. A printed circuit board comprising:
a wiring portion including one or more insulating layers, one or more wiring layers respectively disposed on or in the one or more insulating layers, a first pad disposed on a lowermost insulating layer of the one or more insulating layers, and a second pad disposed on an uppermost insulating layer of the one or more insulating layers;
a first solder resist layer disposed on a lower side of the wiring portion to cover at least a portion of the first pad, the first solder resist layer having a first opening, on the first pad;
a second solder resist layer disposed on an upper side of the wiring portion to cover at least a portion of the second pad;
a first surface treatment layer disposed on at least a portion of the first pad; and
a barrier layer disposed on the first solder resist layer,
wherein the barrier layer includes an inorganic oxide film.

12. The printed circuit board of claim 11, wherein the barrier layer includes at least one of Al₂O₃, TiO₂, ZnO, and SiO₂.

13. The printed circuit board of claim 11, wherein the barrier layer is disposed on a lower surface of the first solder resist layer.

14. The printed circuit board of claim 13, wherein the barrier layer is disposed along an inner wall of the first opening and at least a portion of the first surface treatment layer.

15. The printed circuit board of claim 12, further comprising:
a metal post disposed on at least a portion of the second pad.

16. The printed circuit board of claim 11, wherein a thickness of the barrier layer is less than a thickness of the first pad.

17. The printed circuit board of claim 11, wherein the second solder resist layer has a second opening disposed on the second pad.

18. The printed circuit board of claim 11, wherein the first and second solder resist layers include a thermosetting resin, wherein an inorganic filler is dispersed in the thermosetting resin

19. The printed circuit board of claim 11, wherein the first and second solder resist layers include a photosensitive insulating resin.
